(19) United States
(12) Patent Application Publication
(10) Pub. No.: US 2025/0313986 A1
(43) Pub. Date: Oct. 9, 2025

(54) APPARATUS AND METHOD FOR GROWTH OF GADOLINIUM GALLIUM GARNET CRYSTAL

(71) Applicant: Luxium Solutions, LLC, Hiram, OH (US)

(72) Inventors: Abdelmounaim AHMINE, Grenoble (FR); Drew T. HAVEN, Milford, NH (US)

(21) Appl. No.: 19/195,788

(22) Filed: May 1, 2025

Related U.S. Application Data
(63) Continuation of application No. 19/173,371, filed on Apr. 8, 2025, now abandoned.
(60) Provisional application No. 63/631,160, filed on Apr. 8, 2024.

(51) Int. Cl. C30B 15/20; C30B 15/10; C30B 29/28

(52) U.S. Cl. CPC C30B 15/20; C30B 15/10; C30B 29/28

(57) ABSTRACT

A gadolinium gallium garnet single crystal and method of forming said crystal is disclosed. The single gadolinium gallium garnet crystal can have a diameter of greater than 102 mm and a density of dislocations of less than 1 cm⁻² in a central 80% of the crystal.

### CROSS-REFERENCE TO RELATED APPLICATION(S)

This application is a continuation application of and claims priority under 35 U.S.C. § 120 to U.S. patent application Ser. No. 19/173,371, entitled “APPARATUS AND METHOD FOR GROWTH OF GADOLINIUM GALLIUM GARNET CRYSTAL,” by Abdelmounaim AHMINE et al., filed Apr. 8, 2025, which claims priority under 35 U.S.C. § 119(e) to U.S. Provisional Patent Application No. 63/631, 160, entitled “APPARATUS AND METHOD FOR GROWTH OF GADOLINIUM GALLIUM GARNET CRYSTAL,” by Abdelmounaim AHMINE et al., filed Apr. 8, 2024, which are both assigned to the current assignee hereof and are incorporated herein by reference in their entirety.

### FIELD OF DISCLOSURE

The present disclosure is directed generally to single crystal components and particularly to single crystal ingots, methods for forming such ingots, and processing equipment used in connection with the formation of single crystal ingots.

### BACKGROUND

The telecom industry grows very fast requiring larger production volumes and higher quality requirements also making the pressure on pricing/cost on the contributors to the market. In the information transmission process using optical means the isolation of back reflections is necessary and is performed with the help of optical isolators based on Faraday rotators. The principal material for such Faraday rotators is known to be mainly Yttrium Iron Garnet (YIG=Y₃Fe₅O₁₂) doped and co-doped synthesized under the form of films. Due to the incongruent melting, such YIG films cannot be obtained using bulk crystallization techniques. Therefore, liquid phase epitaxial growth method (LPE) must be used instead. Such method relies highly on the so-called epi-ready substrates that need to have near to perfect surface quality (in terms of local defects, power, waviness and roughness lower than 1-2 nm), low density for dislocations (acceptable max up to few per cm²), low stress level and good matching of the lattice parameter compared to the lattice parameter of the layer to be grown epitaxially, as well as the homogeneity of the lattice parameter (its variation within the substrate). Gadolinium Gallium Garnet (GGG) crystals, natural or doped (SGGG, NGG), can be used as substrates for the LPE of magneto-optical YIG films (natural or doped).

However, growing GGG substrates with the required specifications mentioned above does not come without its challenges. Specifically, its implementation has not been widespread partly due to cost and size limitations due to forming technologies as well as defect formation. To date, the industry has focused on growing gadolinium gallium garnet utilizing Czochralski (CZ) techniques to grow ingots. In this regard, single crystal gadolinium gallium garnet in one geometric configuration holds much industrial promise, but has been increasingly difficult to produce. GGG crystals are prone to dissociations and material inclusions that lead to dislocations. In particular, a non-optimized temperature field during CZ crystal growth, in particular near the solidification interface (melt/crystal) causing instabilities of the last (rapid melting/crystallization), is often at the origin of the generation and multiplication of dislocations in GGG ingots. Additionally, Ga vacancies at octahedral and tetrahedral would lead to the lattice parameter variation. In this regard, since GGG have large lattice parameter, dislocations cannot be removed once they are generated inside a GGG ingot during growth.

Moreover, since GGG wafers are often used for liquid phase epitaxy of other films, any defect in the GGG substrate translates to subsequent growth in those other films. Scaling size while controlling processing costs and reducing inclusions has been a challenge in the industry. For example, repeatable production of large-sized sheets of GGG have not been developed for reliable manufacturing. Therefore, further improvements in apparatuses and methods of growing large-sized gadolinium gallium garnet sheets are desired.

### BRIEF DESCRIPTION OF THE DRAWINGS

The present disclosure may be better understood, and its numerous features and advantages made apparent to those skilled in the art by referencing the accompanying drawings. Embodiments are illustrated by way of example and are not limited in the accompanying figures.

FIG. 1 includes a schematic view of a crystal growth apparatus, according to one embodiment of the present disclosure.

FIG. 2 includes an illustration of growth of the crystal utilizing the apparatus of FIG. 1.

FIG. 3 includes an illustration of a perspective view of a gadolinium gallium garnet crystal, according to one embodiment.

FIG. 4 includes an illustration of a gadolinium gallium garnet crystal, according to one embodiment.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. According to various embodiments, new gadolinium gallium garnet single crystals, crystal growth apparatus, particularly, a Czochralski growth apparatus, and methods for growing single crystal ingots are provided.

The foregoing has outlined rather broadly and in a non-limiting fashion the features and technical advantages of the present invention in order that the detailed description of the invention that follows may be better understood. Additional features and advantages of the invention will be described hereinafter. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the scope of the invention as set forth in the appended claims.

As used herein, the terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about”, “approximately”, or “substantially” is intended to mean that a value of a parameter is close to a stated value or position. However, minor differences may prevent the values or positions from being exactly as stated. Thus, differences of up to ten percent (10%) (and up to twenty percent (20%) for semiconductor doping concentrations) for the value are reasonable differences from the ideal goal of exactly as described.

Group numbers corresponding to columns within the Periodic Table of Elements based on the IUPAC Periodic Table of Elements, version dated Nov. 28, 2016.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the scintillation, radiation detection and ranging arts.

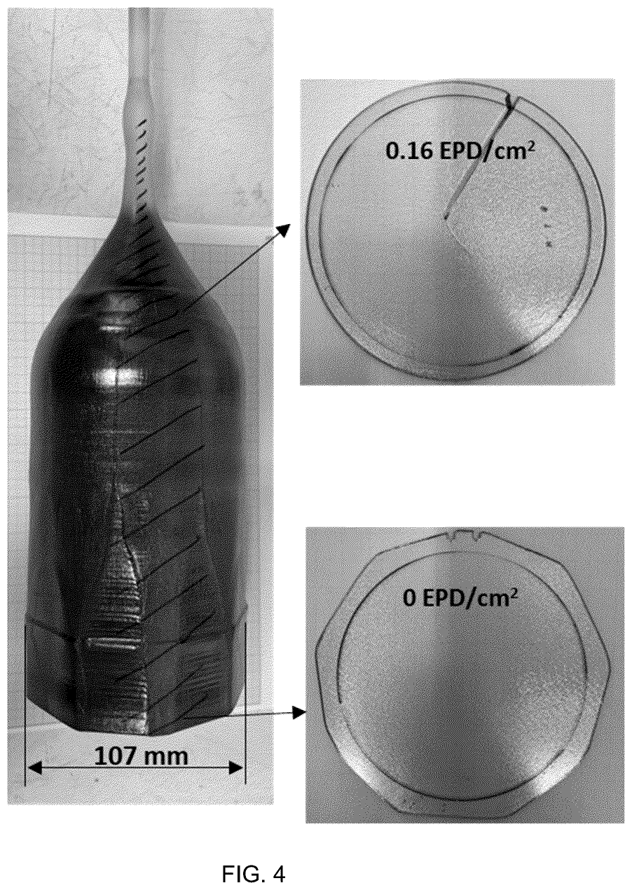

Apparatuses and methods as described herein can be used to grow gadolinium gallium garnet ingots with a diameter larger than 4 inches having a dislocation density of less than 1 cm⁻² on 80% of a central surface of a substrate, as seen in FIG. 4. As seen in FIG. 4, the ingot can be sliced to form a substrate 400. The ingot can have a dislocation density of less than 1 cm⁻² on 80% of a central surface 401 of a substrate 400. Also seen in FIG. 4, as comparison, is a substrate 402, when not formed according to embodiments described herein, that can have a dislocation density 404 of greater than 1 cm⁻² on 80% of a central surface 403 of a substrate 402.

Gadolinium gallium garnet shows strong tendency of spiral or acentric growth thus limiting the size of growth to less than 4 inches. Moreover, the larger the ingot, the more difficult it is to control the temperature gradients in the vicinity of the growth interface. However, according to various embodiments of the present disclosure, new gadolinium gallium garnet crystals, a crystal growth apparatus, and methods for growing single crystals are provided.

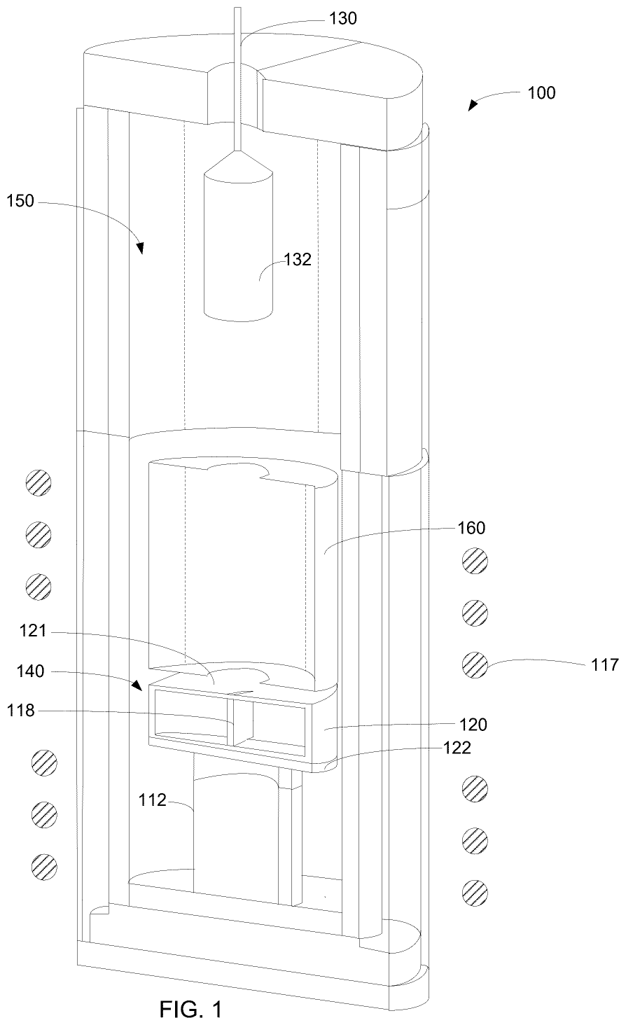

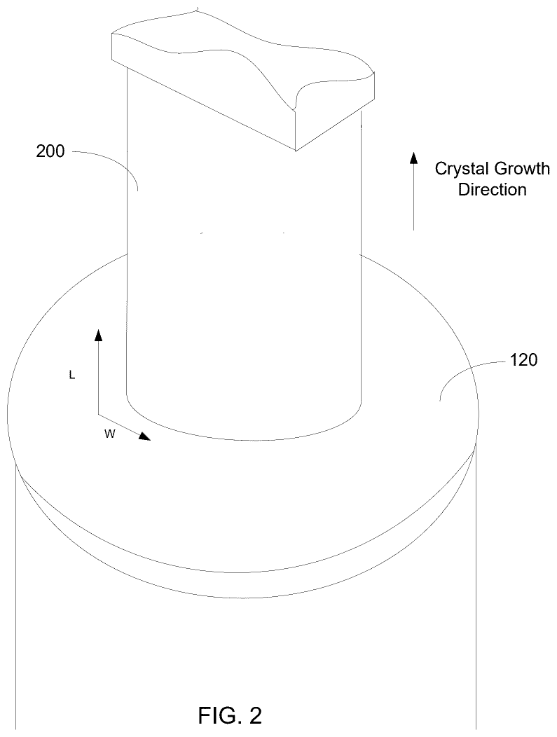

Description of these various embodiments begins with a discussion of the Czochralski growth apparatus 100 illustrated in FIGS. 1 and 2. As used herein, the term Czochralski refers to a technique that is generally understood in the industry of single crystal fabrication, and particularly as applied to gadolinium gallium garnet single crystal growth.

The Czochralski growth apparatus 100 includes several main components, including a pedestal 112 supporting the crucible 140. Pedestal 112 is generally provided to mechanically support the apparatus while thermally isolating the crucible 140 from the work surface on which the Czochralski apparatus is provided, to attenuate heat transmission from the crucible 140 to the work surface. In this context, the pedestal 112 is generally formed of a refractory material capable of withstanding elevated temperatures on the order of 1800° C. While various refractory metals and ceramics may be utilized, porous alumina is particularly suited for the pedestal 112. In one embodiment, vent holes can be provided in pedestal 112 to further improve thermal isolation.

Crucible 140 is provided for containing the melted raw material utilized for growing the single crystal. In the context of GGG single crystals, whose chemical formula is Gd₃Ga₅O₁₂, the raw material is a stochiometric mixture of highly pure Gd₂O₃ and Ga₂O₃ powders. The crucible 140 is typically formed of a refractory metal that is adapted to be heated through exposure to the magnetic field generated by an inductive heating element 117. The crucible is desirably formed of iridium although other materials may be utilized such as tungsten, molybdenum, and in the case of growth of silicon carbide single crystals, graphite. More generally speaking, the materials are desired to have a higher melting point than the crystal being grown, should be wet by the melt, and not react chemically with the melt. The inductive heating element 117 can be an RF coil, having multiple turns forming a helix. Another iridium component in the form of a ring, called a reflector 121, is placed on the upper part of the crucible 140. The reflector 121 can better control the temperature gradients in the growing ingot and in the vicinity of the solidification interface by preventing heat losses by radiation. Also, the reflector 121 helps to prevent the melt from evaporating from the crucible 140.

In one embodiment, thermal insulation of crucible 140, in which crystallization (solidification) occurs, is ensured by layers of a refractory material generally surrounding the lateral sides and a top insulating chimney 150. The insulation layers may be formed of porous alumina materials, for example, although other insulation materials may be utilized such as alumina felt; zirconia felt, aluminum nitride, and fused silica (quartz).

The crucible 140 can be placed between the pedestal 112 and the chimney 150. According to one embodiment, the crucible 140 can have cylindrical or conical structures, with a flat or rounded bottom. The inductive heating element 117 shown in FIG. 1 also has an aspect ratio similar to that of the crucible 140, namely being greater than 3:2.

The chimney 150 can have two openings on either side that facilitate the passage of the pulling rod 110 with grown GGG crystal attached on its lower end. The chimney 150 provides a temperature control area to further aid in the growth of the crystal. The chimney 150 maintains a thermal control gradient inside the ingot and protects from the external environment.

In the Czochralski growth apparatus 100, the monocrystalline seed 130 is attached to the bottom of the pulling rod 129, which is made of refractory material such as alumina. The upper part of the pulling rod 129 is attached to the translation and rotation systems and to a weighing cell. These latest, together with the power generator, are connected to a computer containing an “automatic growth” software that not only allows to program the translation and rotation speeds at different stages of the growth, but also controls the diameter of the growing crystal by adjusting the heating power to obtain the appropriate weight gain, commonly known as the growth rate (g/h).

While a more detailed discussion is provided below regarding the growth process and operation of the growth apparatus, the process generally calls for lowering a GGG seed crystal 130 through the chimney 150 to make contact with the liquid GGG melt contained into the crucible, exposed through the crucible reflector and through the chimney 150. In the embodiment illustrated, the chimney 150 is passive, that is, does not contain active heating elements. However, the chimney 150 may be active, incorporating temperature control elements such as heating elements.

Focusing further on operation of the growth apparatus 100, typically crystal growth begins with formation of a melt in the crucible. Here, the crucible is filled with a feed GGG material. The feed material is generally provided by introduction through feed tubes, not shown. The melt is initiated and maintained by inductive heating at a temperature of about the melting temperature of GGG (around 1730° C.), by energizing inductive heating element 117. Heating by induction is affected by heating of the crucible 120, transmitting heat into the material contained therein. Fine control of the heating power during loading and melting of the GGG raw material is necessary in order to avoid overheating of the melt which favors the volatilization of gallium modifying the stoichiometry of the melt. Mastery of the latter is important in order to obtain the targeted lattice parameters for the obtained ingot at the end.

After dipping the seed into the melted GGG, stabilizing and initiating the growth, the GGG seed is raised and the growing single crystal 132 spreads to form a neck portion. The neck portion spreads to full diameter, initiating the growth of the full diameter portion or main body of the single crystal (cylindrical part). The diameter can be greater than 25 mm, such as greater than 30 mm, 35 mm, 40 mm, or 50 mm and less than 153 mm, such as less than 140 mm, 127 mm, or 114 mm.

The single crystal is then raised through the chimney 150 up to colder zones of the chimney and the furnace. As the single crystal 132 is pulled toward the upper part of the thermal configuration, the single crystal 132 enters into a second thermal environment, within the chimney, which is different from the thermal environment near the crucible 140. In essence, the controlled thermal gradient difference as the single crystal goes from inside the crucible 140 to the upper heating zone prevents catastrophic failure of crystal 132. The crystal is generally pulled up within a range of about 1 to 10 millimeters per hour.

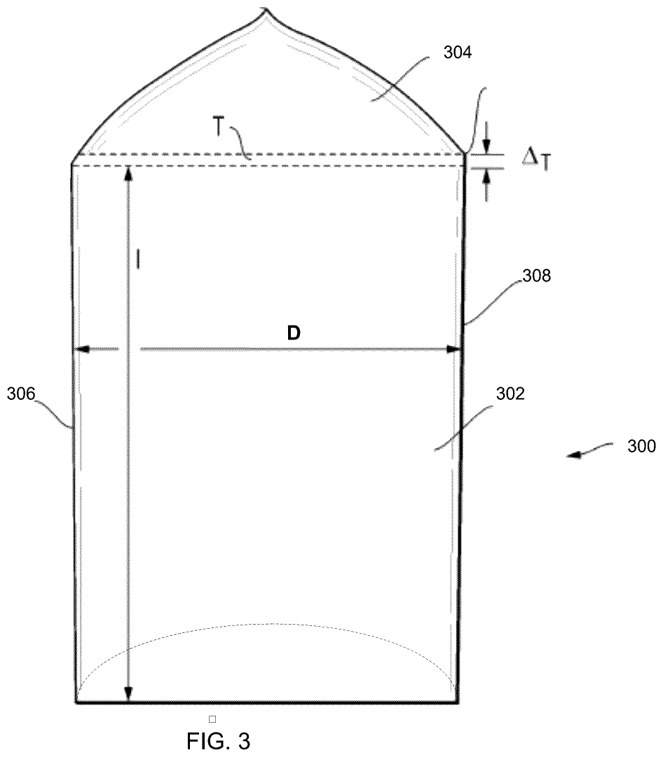

At this point in the crystal growing process, a neck is grown, representing a sub-maximum width of the single crystal. Turning briefly to the full-length single crystal 300 shown in FIG. 3, the single crystal 300 includes the main body 302 and a neck 304. In one embodiment, the main body may be cylindrical and the neck may be conical. The initial portion of the neck extending from seed end is desired to have a minimum geometry, such as on the order of a few centimeters long.

Upon continued pulling of the seed crystal 130, the neck widens to maximum width, which is the length of the die 118. Turing briefly to FIG. 3, an illustration of a grown GGG crystal 300 grown is provided. The crystal 300 represents an as-formed full-length crystal that was acceptable for further processing into useful components. Growth of large, with a diameter greater than 3 inches, GGG crystals is historically difficult and problematic. As described earlier, controlling the radial temperature gradients and the stability of the solidification interface become more challenging with increasing diameter. Also, residual stresses due to variations of lattice parameters are one of the limiting factors for diameter increasing over 3 inches.

The unique properties of GGG thus present issues for scaling up boules to a larger size, i.e., larger than 4 squared inches. The larger the desired crystal, the more opportunity for such changes in plane orientation and the more difficult to grow an ingot of single orientation substrates. As such, growth of a GGG crystal of greater than 4 square inches, as seen in FIG. 3, is unique and unexpected.

Turning back to FIG. 1, the thermal gradient may be adjusted by manipulating the geometry of chimney 150 in combination with reflector 21 at an environment of between 0% O₂ and 30% O₂, such as between 0% and 25%, or between 0% and 10% O₂. Precise growth environment control minimizes melt decomposition and reduces the volatility of gallium garnet that could lead to an unsuccessful crystalline growth. In the particular embodiment, raising the crucible at a particular end raises the temperature at that end, while lowering the crucible lowers the temperature at that end.

The overall temperature profile along the length of the die is generally such that the center of the die has the highest temperature, with temperature falling off to the edges of the die. Ideally, the curve is symmetrical, where temperature from the center to each end of the die falls off uniformly, creating generally similar temperature gradients from the center of the die to each end of the die. While adjustment of the thermal gradient has been described herein in connection with use of the crucible, other gradient systems may be utilized. For example, thermal shields may be used along with heat sinks, which act to draw heat away from the die. In the manner known in the art, heat sinks may take on the form of a heat exchanger, such as those that have a fluid flowing therethrough for carrying thermal energy away from the heat sink.

Upon the creation of a full-length single crystal with a diameter greater than 4 inches, the single crystal ingot is broken free from the melt by pulling, and temperature is stabilized by maintaining the single crystal within the upper part of the chimney 150. Thereafter, a controlled cooling of the crystal is affected. Typically, cooling is carried out at a rate not greater than about 300° C./hr, such as not greater than about 200, 100, or even 50° C./hr. According to an embodiment, the cooling rate is not less than about 10° C./hr., such as within a range of about 5 to 50° C./hr. The relatively slow cooling rates are generally dictated by several parameters, including the mass of the crystal. Here, in the case of relatively large single crystals, it is not uncommon for the single crystal to have a mass greater than about 10 kg.

Following the growth, separation and cool down of the single crystal, machining operations typically follow. It is generally desired that the single crystal be near-net shape, but oftentimes machining is performed to shape the single crystal into the desired geometric configurations for commercial use. Accordingly, grinding, lapping, polishing and the like, or bulk material removal/shaping such as wire sawing or cleaving and the like may be utilized to manipulate the single crystal into a desired component or components, such as epi-ready substrates of different diameters.

Turning to the single crystal itself, as seen in FIG. 3 the single crystal is in the form of GGG crystal formed with less than 1 dislocation/cm² on about 80% of the surface. In one embodiment, the single crystal may be doped with an element such as Fe, Cu, Ag, Zn, Cd, Sn, Zr, Hf, Al, In, Si, Mg, Ge, or Nb. Typically, the single crystal can have a diameter of not less than about 100 cm, such as not less than about 105 cm, or 105 cm, or even 120 cm. Further, according to a particular feature, the diameter is no greater than 1000 mm, such as greater than 250 mm, or no greater than 240 mm. Dislocations can be linear defects that propagate along the length of the crystal. In one embodiment, dislocations can be edge pit dislocations. In one embodiment, a grown crystal can have less than 5 dislocations/cm², or such as less than 2 dislocations/cm², or such as less than 1 dislocation/cm², or such as less than 0.5 dislocation/cm². To determine the dislocations, a slice of between 2.9 mm and 3.3 mm of the ingot is taken, machines, and chemically etched to determine an edge pit density. The number of dislocations is determined by the central most 80% of the crystal. In one embodiment, the edge pit dislocations are about 0.3 cm⁻² for the central most 80% of the substrate.

### EXAMPLES

Example 1, a crystal having dimensions 105±3×100±10 (D×L in mm). The following process flow was used to form Example 1.
a. Set up furnace with growth components: crucible, reflector, and insulation package (hotzone).
b. Inject gases inside the furnace, with a mixture of O₂ and other inert gas like N₂, Ar₂ or CO₂.
c. Turn on power generator (50 kW).
d. Ramp power at 3% per minute until complete melting of the GGG contained in the crucible (˜1730° C.).
e. Start feeder and add about 15 kg of feed material (mixture of Ga₂O₃ and Gd₂O₃) into crucible.
f. Allow melt to stabilize for 2 hours.
g. Lower seed and contact melt at midpoint.
h. Adjust temperature to form a disc around the seed of approximatively the same diameter as the seed.
i. Start upward translation of puller at 3 mm/hr. Once growth rate is stabilized, monitor growth shape and dimensions of the entire crystal (seed, shoulder, body); pulling rate; rotation rate; regulation parameters; extraction height and rate at the end of growth; cooling rate.
j. Adjust the temperature and/or temperature gradient to maintain uniform liquid film height of 0.3±0.1 mm at die interface while growing body of crystal at 3 mm/hr.
k. After cooling, the GGG ingot is removed manually from the furnace and transferred for characterization, machining, and polishing.

### Other Examples

Through use of various features of the embodiments of the present invention, such as utilization of a high aspect ratio crucible and reflector, high aspect ratio heating element, high aspect ratio insulations assembly, GGG single crystal ingots having the foregoing desirable geometric and mass features such as minimum diameter and maximum dislocation densities may be successfully formed.

### Various Embodiments

Embodiment 1. A gadolinium gallium garnet single crystal can have a single gadolinium gallium garnet crystal with a diameter greater than 102 mm and a density of dislocations of less than 1 cm⁻² in a central 80% of the crystal.

Embodiment 2. The gadolinium gallium garnet crystal of embodiment 1, where the diameter of the gadolinium gallium garnet based single crystal is greater than 105 mm.

Embodiment 3. The gadolinium gallium garnet crystal of embodiment 1, where the diameter of the gadolinium gallium garnet based single crystal is greater than 115 mm.

Embodiment 4. The gadolinium gallium garnet crystal of embodiment 1, where the diameter of the gadolinium gallium garnet based single crystal is greater than 120 mm.

Embodiment 5. The gadolinium gallium garnet crystal of embodiment 1, where the diameter of the gadolinium gallium garnet based single crystal is greater than 150 mm.

Embodiment 6. The gadolinium gallium garnet crystal of embodiment 1, where the diameter of the gadolinium gallium garnet based single crystal is not greater than 1000 mm.

Embodiment 7. The gadolinium gallium garnet crystal of embodiment 1, where the gadolinium gallium garnet crystal has a density of dislocation of less than 0.5 dislocation/cm² in the central 80% of the crystal.

Embodiment 8. A method of growing a gadolinium gallium garnet crystal and include bringing a seed crystal in contact with a gadolinium gallium garnet base melt, pulling the seed crystal to grow the gadolinium gallium garnet based single crystal, and cooling the gadolinium gallium garnet based single crystal after it has reached a diameter that is greater than 102 mm, where the gadolinium gallium garnet based single crystal has a density of dislocations of less than 1 cm⁻² in a central 80% of the crystal.

Embodiment 9. The method of embodiment 8, where the diameter of the gadolinium gallium garnet based single crystal is greater than 105 mm.

Embodiment 10. The method of embodiment 8, where the diameter of the gadolinium gallium garnet based single crystal is greater than 115 mm.

Embodiment 11. The method of embodiment 8, where the diameter of the gadolinium gallium garnet based single crystal is greater than 120 mm.

Embodiment 12. The method of embodiment 8, where the diameter of the gadolinium gallium garnet based single crystal is greater than 150 mm.

Embodiment 13. The method of embodiment 8, where the diameter of the gadolinium gallium garnet based single crystal is not greater than 1000 mm.

Embodiment 14. The gadolinium gallium garnet crystal of embodiment 8, where the crystal was grown using a Czochralski method.

Embodiment 15. The method of embodiment 8, wherein cooling is carried out at a rate not greater than about 300° C./hr.

Embodiment 16. The method of embodiment 8, wherein cooling is carried out at a rate not greater than about 200° C./hr.

Embodiment 17. The method of embodiment 8, wherein cooling is carried out at a rate not greater than about 150° C./hr.

Embodiment 18. The method of embodiment 8, wherein cooling is carried out at a rate not greater than about 100° C./hr.

Embodiment 19. The method of embodiment 8, wherein cooling is carried out at a rate not greater than about 50° C./hr.

Embodiment 20. The method of embodiment 8, wherein cooling is carried out at a rate not greater than about 50° C./hr, not less than about 10° C./hr.

Embodiment 21. The method of embodiment 8, can further include dynamically adjusting a thermal gradient along a die as the seed crystal is being pulled.

Embodiment 22. The method of embodiment 8, wherein the gadolinium gallium garnet base melt is within a crucible, wherein the crucible comprises iridium.

The foregoing embodiments represent a departure from the state-of-the-art. Notably, the embodiments herein include a combination of features not previously recognized in the art and facilitate performance improvements.

The above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

The Abstract of the Disclosure is provided to comply with Patent Law and is submitted with the understanding that it will not be used to interpret or limit the scope or meaning of the claims. In addition, in the foregoing Detailed Description of the Drawings, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all features of any of the disclosed embodiments. Thus, the following claims are incorporated into the Detailed Description of the Drawings, with each claim standing on its own as defining separately claimed subject matter.

What is claimed is:

1. A gadolinium gallium garnet single crystal, comprising:
a single gadolinium gallium garnet crystal having a diameter greater than 102 mm and a density of dislocations of less than 1 cm⁻² in a central 80% of the crystal.

2. The gadolinium gallium garnet crystal of claim 1, wherein the diameter of the gadolinium gallium garnet based single crystal is greater than 105 mm.

3. The gadolinium gallium garnet crystal of claim 1, wherein the diameter of the gadolinium gallium garnet based single crystal is greater than 115 mm.

4. The gadolinium gallium garnet crystal of claim 1, wherein the diameter of the gadolinium gallium garnet based single crystal is greater than 120 mm.

5. The gadolinium gallium garnet crystal of claim 1, wherein the diameter of the gadolinium gallium garnet based single crystal is greater than 150 mm.

6. The gadolinium gallium garnet crystal of claim 1, wherein the diameter of the gadolinium gallium garnet based single crystal is not greater than 1000 mm.

7. The gadolinium gallium garnet crystal of claim 1, wherein the gadolinium gallium garnet crystal has a density of dislocation of less than 0.5 dislocation/cm⁻² in the central 80% of the crystal.

8. A method of growing a gadolinium gallium garnet crystal, comprising:
bringing a seed crystal in contact with a gadolinium gallium garnet base melt;
pulling the seed crystal to grow the gadolinium gallium garnet based single crystal; and
cooling the gadolinium gallium garnet based single crystal after it has reached a diameter that is greater than 102 mm, wherein the gadolinium gallium garnet based single crystal has a density of dislocations of less than 1 cm⁻² in a central 80% of the crystal.

9. The method of claim 8, wherein the diameter of the gadolinium gallium garnet based single crystal is greater than 105 mm.

10. The method of claim 8, wherein the diameter of the gadolinium gallium garnet based single crystal is greater than 115 mm.

11. The method of claim 8, wherein the diameter of the gadolinium gallium garnet based single crystal is greater than 120 mm.

12. The method of claim 8, wherein the diameter of the gadolinium gallium garnet based single crystal is greater than 150 mm.

13. The method of claim 8, wherein the diameter of the gadolinium gallium garnet based single crystal is not greater than 1000 mm.

14. The method of claim 8, wherein the crystal was grown using a Czochralski method.

15. The method of claim 8, wherein cooling is carried out at a rate not greater than about 300° C./hr.

16. The method of claim 8, wherein cooling is carried out at a rate not greater than about 200° C./hr.

17. The method of claim 8, wherein cooling is carried out at a rate not greater than about 150° C./hr.

18. The method of claim 8, wherein cooling is carried out at a rate not greater than about 100° C./hr.

19. The method of claim 8, wherein cooling is carried out at a rate not greater than about 50° C./hr.

20. The method of claim 8, wherein the gadolinium gallium garnet base melt is within a crucible, wherein the crucible comprises iridium.
